(19) United States
(12) Patent Application Publication
(10) Pub. No.: US 2026/0154808 A1
(43) Pub. Date: Jun. 4, 2026

(54) METHOD FOR OBTAINING MEASUREMENTS OF SEMICONDUCTOR STRUCTURES FROM A SINGLE WEDGE CUT OF AN INSPECTION VOLUME

(71) Applicant: Carl Zeiss SMT GmbH, Oberkochen (DE)

(72) Inventors: Johannes DIETERLE, Aalen (DE); Dmitry KLOCHKOV, Schwaebisch Gmuend (DE); Thomas KORB, Schwaebisch Gmuend (DE)

(21) Appl. No.: 19/457,928

(22) Filed: Jan. 23, 2026

Related U.S. Application Data
(63) Continuation of application No. PCT/EP2024/067871, filed on Jun. 25, 2024.

(30) Foreign Application Priority Data
Aug. 1, 2023 (DE) 10 2023 120 462.9

(51) Int. Cl. G06T 7/00; H01J 37/28; H01J 37/31

(52) U.S. Cl. CPC G06T 7/001; H01J 37/28; H01J 37/31; G06T 2207/10061; G06T 2207/30148

(57) ABSTRACT

A method obtains measurements of semiconductor structures from a single wedge cut of an inspection volume. The method comprises obtaining the wedge cut by exposing a cross-section surface in the inspection volume by milling into the inspection volume with a FIB column arranged under a slant angle, and imaging the cross-section surface with a charged particle beam imaging system. The method also comprises determining positions of cross-section features of semiconductor structures in the wedge cut, and determining reference positions of the cross-section features from at least one reference image of the semiconductor structures. The method further comprises obtaining the one or more measurements of the semiconductor structures using lateral displacements between the positions of the cross-section features and the reference positions.

### CROSS-REFERENCE TO RELATED APPLICATIONS

The present application is a continuation of, and claims benefit under 35 USC 120 to, international application No. PCT/EP2024/067871, filed Jun. 25, 2024, which claims benefit under 35 USC 119 of German Application No. 10 2023 120 462.9, filed Aug. 1, 2023. The entire disclosure of each of these applications is incorporated by reference herein.

### FIELD

The present disclosure relates to a three-dimensional circuit pattern inspection and measurement technique by cross-sectioning of integrated circuits. The present disclosure relates to a three-dimensional circuit pattern inspection technique by cross-sectioning of inspection volumes at measurement sites of semiconductor wafers comprising integrated circuits. The present disclosure relates to a method, computer program, a computer-readable medium and a corresponding dual beam device for obtaining measurements of semiconductor structures from a wedge cut of an inspection volume at a measurement site of a semiconductor wafer. A method can employ milling of a cross-section surface into an inspection volume of a wafer under a slanted angle and imaging the slanted cross-section surface with a charged particle beam imaging system. A method, computer program, computer-readable medium and corresponding dual beam device can be utilized for quantitative metrology, defect detection, process monitoring, defect review, and inspection of integrated circuits within semiconductor wafers.

### BACKGROUND

Manufacturing of wafers comprising semiconductor structures typically includes a relatively complex sequence of deposition and removal of physical substances at nano-scale resolutions. Therefore, extracting measurements from the manufactured 3D structures is typically desirable to monitor the manufacturing processes.

A wafer made of a thin slice of silicon usually serves as the substrate for microelectronic devices containing semiconductor structures built in and upon the wafer. The semiconductor structures are usually constructed layer by layer using repeated processing steps that involve repeated chemical, mechanical, thermal and optical processes. A semiconductor wafer typically has a diameter of 300 mm and comprises a plurality of several sites, so called dies, each comprising at least one integrated circuit pattern, e.g., for a memory chip or for a processor chip. Semiconductor wafers typically run through about 1,000 process steps, and within the semiconductor wafer, about 100 and more parallel layers are formed, comprising the transistor layers, the layers of the middle of the line, and the interconnect layers and, in memory devices, a 3D array of memory cells.

Fabricated semiconductor structures usually correspond to prior knowledge about their internal structure. The semiconductor structures are manufactured from a sequence of layers parallel to a substrate. For example, in a logic type sample, metal lines run parallel in metal layers or HAR (high aspect ratio) structures and metal vias run perpendicular to the metal layers. The angle between metal lines in different layers is either 0° or 90°. On the other hand, for VNAND type structures it is known that their cross-sections are circular on average.

Dimensions, shapes and placements of the semiconductor structures and patterns are often subject to several influences. A step in manufacturing is the photolithography process. Photolithography is a process used to produce patterns on the substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., using optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers.

Due to the growing integration density in the semiconductor industry, photolithography masks are used image increasingly smaller structures onto wafers. In general, the aspect ratio and the number of layers of integrated circuits constantly increases and the structures are growing into the third (vertical) dimension. The current height of the memory stacks exceeds a dozen of microns. In contrast, in general the feature size is becoming smaller. The minimum feature size or critical dimension is typically below 10 nm, for example 7 nm or 5 nm, and is expected to approach feature sizes below 3 nm in near future. While the complexity and dimensions of the semiconductor structures are growing into the third dimension, the lateral dimensions of integrated semiconductor structures are becoming smaller. Producing the small structure dimensions imaged onto the wafer involves photolithographic masks or templates for nanoimprint photolithography with ever smaller structures or pattern elements.

As this fabrication process is complicated and highly non-linear, optimization of production process parameters can be difficult. As a remedy, an iteration scheme called process window qualification (PWQ) can be applied. In each iteration a test wafer is manufactured based on the currently best process parameters, with different dies of the wafer being exposed to different manufacturing conditions. By detecting and analyzing the test structures with devices for quantitative metrology and defect-detection, the best manufacturing process parameters can be selected. In this way, production process parameters can be tweaked towards optimality.

On account of the relatively structure sizes of the pattern elements of photolithographic masks or templates and the relatively complex production process of semiconductor structures, it is usually not possible to exclude errors during wafer production. Hence, in semiconductor process control wafer inspection, review, and metrology are used to monitor defects. Traditionally, measurements of 2D semiconductor structures were taken manually by experts. However, due to the three-dimensionality of the semiconductor structures on the wafer, three-dimensional measurements are desired, which allow for a more accurate monitoring of the production process.

A common way to generate tomographic data, i.e., a 3D imaging dataset, from semiconductor samples on a nanometer scale is the so-called slice and imaging approach carried out, for example, by a dual beam device. In such an apparatus, two particle optical systems are arranged at an angle. The first particle optical system can be a scanning electron microscope (SEM). The second particle optical system can be a focused ion beam optical system (FIB), using for example gallium (Ga) ions. A focused ion beam (FIB) of Gallium ions is used to cut off layers at an edge of a semiconductor sample slice by slice and every cross-section is imaged using a scanning electron microscope (SEM). The two particle optical systems might be oriented perpendicular or at an angle between 45° and 90°. The generated imaging datasets are dense (e.g., comprising thousands of images) and, therefore, can be challenging with respect to scalability, robustness and repeatability for taking measurements.

For example, WO 2021/083581 A1 discloses a method for measuring shape deviations of 3D HAR structures in FIB-SEM tomography. The method comprises obtaining an imaging dataset of 2D cross-section images parallel to the wafer surface using a slice and imaging technique. A template of cross-section image features representing a HAR structure of interest is generated, and instances of this template are detected in the 2D cross-section images of the imaging dataset. The detected instances are assigned to different 3D HAR structures, e.g., based on the distance of the center coordinates of the instances in adjacent 2D cross-section images. From the detected instances assigned to the same 3D HAR structure the surface of the 3D HAR structure is reconstructed and parameters characterizing the geometry of the entire semiconductor structure are obtained.

Obtaining parallel slices of a wafer for measuring parameters of semiconductor structures may use large amounts of data and leads to low throughput. To reduce the amount of data used for measuring parameters of semiconductor structures, WO 2021/180600 A1 discloses a method for measuring parameters using multiple wedge cuts, i.e., cross-section images obtained by milling into the wafer using a FIB SEM at a slanted angle, such as between 25° and 45°, with respect to a surface of a wafer support table. In the wedge cut the depth of a pixel can be obtained from its lateral position. To minimize runtime and increase the throughput, a single wedge cut can be sufficient to generate measurements of repetitive semiconductor structures in a wafer. To this end, a representative semiconductor structure can be obtained from the single wedge cut as illustrated in FIG. 24 and FIG. 25 of WO 2021/180600 A1 by combining a number of cross-section surface features from different instances of the same semiconductor structure into a single representative semiconductor structure. Due to distortions in the wedge cut the accuracy of the location of the cross-section surface features and, thus, of the representative semiconductor structure and the measurements obtained thereof is often insufficient.

### SUMMARY

The disclosure seeks to provide a more accurate method for obtaining measurements of 3D semiconductor structures from a single wedge cut. The disclosure seeks to obtain measurements of 3D semiconductor structures relatively quickly and with increased throughput. The disclosure seeks to provide a method for generating a 3D representative semiconductor structure from a single wedge cut with improved accuracy. The disclosure seeks to obtain measurements of 3D semiconductor structures with low memory. The disclosure seeks to provide a method for reviewing critical dimensions of semiconductor structures on a wafer. The disclosure seeks to provide a method for process window qualification. The disclosure seeks to increase the throughput during quality control or quality assurance processes for wafers. The disclosure seeks to minimize runtimes of quality control or quality assurance methods.

Certain embodiments of the disclosure relate to methods, computer programs, computer-readable media and dual beam devices for obtaining a 3D representative semiconductor structure from a single wedge cut of an inspection volume.

A first embodiment involves a method for obtaining one or more measurements of semiconductor structures from a single wedge cut of an inspection volume, the method comprising: obtaining the wedge cut of the inspection volume by exposing a cross-section surface in the inspection volume by milling into the inspection volume with a FIB column arranged under a slant angle GF, and imaging the cross-section surface with a charged particle beam imaging system to obtain the wedge cut; determining positions of cross-section features of semiconductor structures in the wedge cut; determining reference positions for the cross-section features from at least one reference image of the semiconductor structures; obtaining the one or more measurements of the semiconductor structures in the inspection volume using a reference semiconductor structure and the lateral displacements between the positions of the cross-section features and the reference positions.

A wedge cut refers to an image of a slanted cross-section surface of the inspection volume, e.g., a section of a wafer. The cross-section surface can be obtained by milling into the inspection volume with a FIB column arranged under a slant angle GF between 20° and 80° with respect to a surface of a wafer support table. The slant angle GF can lie within the range of 25° and 45°, such as within the range of 30° and 36°, relative to the wafer surface. Instead of milling, any other delayering method may be used, e.g., a laser. The image of the cross-section surface, the wedge cut, is obtained by imaging the cross-section surface using a charged particle beam imaging system arranged under an angle GE with respect to the normal of the surface of the wafer support table, e.g., an angle GE between 0° and 50°, such as an angle between 0° and 30° or between 0° and 20°, for example 15°.

An inspection volume refers to a subset of a wafer comprising semiconductor structures. The inspection volume can comprise multiple semiconductor structures of the same design. A semiconductor structure refers to any type of structure on a wafer, for example to a high aspect ratio structure such as a VIA or channel.

A cross-section feature refers to a structure in a cross-section image of an inspection volume. A cross-section feature can be from the group comprising points (e.g., centroids, center points, centers of gravity or contour points, etc.), lines (e.g., tangents, intersections, distances, normals, secants, bounding boxes, etc.), curves (e.g., contours, contour sections), edges, geometric shapes (e.g., polygons, circles, ellipses, etc.).

A reference image refers to an acquired or simulated image, e.g., a cross-section image of a reference volume obtained by milling using an arbitrary angle and depth, a top view image of a reference volume, a slice parallel to the wafer support table or a wedge cut of a reference volume. The reference volume can comprise a different inspection volume, e.g., an inspection volume obtained from the same or a similar design and using the same or a similar manufacturing process. Alternatively, the reference volume can be simulated. The at least one reference image can be obtained from a design or model of a wafer, e.g., from a CAD model, or it can be simulated. For such artificial reference images, the appearance of an acquired image can be simulated, e.g., using machine learning methods such as generative adversarial networks that are trained to mimic appearances.

A reference position of a cross-section feature refers to a position of the cross-section feature in the at least one reference image.

A measurement of a semiconductor structure can refer to a spatial measurement of the 3D semiconductor structure that can be used for defect detection, e.g., to a length, a dimension, a diameter, an angle, a volume, a shape, a tilt, a wiggling, to a deviation from some value, e.g., from a standard value or from an average value, or to a statistical measurement thereof, e.g., an average measurement, a variance of a measurement or some other moment of a distribution of measurements obtained from a 3D semiconductor structure, or to some quality measurement obtained from such a distribution of measurements.

By using at least one reference image to obtain the reference positions of the cross-section features, the reference positions can be obtained with increased accuracy, compared, for example, to the assumption of a regular hexagonal grid as reference positions. This is due to the fact that the at least one reference image can comprise, for example, lateral or depth dependent distortions or further imaging effects due to the imaging process such as contrast, sharpness or brightness changes, noise, charging effects, effects due to changes in the shape and size of the electron beam, etc. Since the distortions and further imaging effects are included both in the inspection volume and in the at least one reference image, the reference positions can comprise the same errors as the positions of the cross-section features. Thus, the one or more measurements or the 3D representative semiconductor structure can be obtained with increased accuracy.

The method can use only a single wedge cut of each inspection volume and at least one reference image to obtain measurements of semiconductor structures. The at least one reference image (or a subset thereof) could be re-used to obtain measurements of different inspection volumes having substantially the same design. In this way, machine time, effort, resources, and computation time can be saved.

A single reference image can be sufficient to obtain the reference positions of the cross-section features. By using two or more reference images, the reference positions can be obtained with increased accuracy due to the additional information available. For example, the reference positions can be averaged over all reference images. In addition, different reference images can be used for different depths of the cross-section features. In this way, 3D representative semiconductor structures of various shapes can be generated and examined, e.g., of shapes that vary with depth such that their cross-section features differ in different depths. In this way, the method can be applicable to a wider range of inspection volumes.

The reference positions of the cross-section features in the at least one reference image can be obtained using image analysis methods, e.g., edge detection, contour extraction such as Active Contours, centroid computation, geometric shape fitting, Hough transforms, pattern matching, energy optimization methods such as variational methods or graph cuts, machine learning methods such as object detection, recognition or segmentation methods, etc.

In an example, the method further comprises determining the depths of the cross-section features in the inspection volume. To this end, the position of further cross-section features of further structures in the inspection volume can be determined. Examples of further structures are isolator lines or layers, metal lines or layers, semiconductor lines or layers or word-lines, etc. The further structures can be detected in the wedge cut using image analysis methods, e.g., edge detection, contour extraction such as Active Contours, centroid computation, geometric shape fitting, energy minimization methods such as variational methods or graph cuts, machine learning methods such as object detection, recognition or segmentation methods, etc. These further structures can run, for example, parallel to the wafer surface. Their depth is usually known with relatively high accuracy. Using prior knowledge of the depth of the further structures, the determination of the depth of the cross-section features in the inspection volume is possible.

As indicated, for example, in WO 2021/180600 A1, using prior knowledge of the depth of these further structures, e.g., from a design, the depth of the cross-section features can be obtained relative to the further cross-section features with high precision, e.g., using trigonometric functions and the angles GF and GE. For example, the depth of any boundaries or surfaces of each layer running parallel to the wafer surface is usually known with relatively high precision and, due to the planar fabrication techniques involved in the fabrication of a wafer, constant over a larger area of a wafer.

Alternatively, the depths of the cross-section features can also be determined from their lateral position in the wedge cut in case the slant angles of the FIB and CPB imaging systems and the position of the inspection volume are known.

In an example, cross-section features in the wedge cut are assigned to corresponding cross-section features of the same semiconductor structures in the at least one reference image, e.g., using image analysis methods or machine learning methods, for example registration methods. Based on this assignment, the positions of the cross-section features in the wedge cut can be compared to the reference positions of the cross section features in the at least one reference image. For example, each cross-section feature in the wedge cut is assigned to a cross-section feature in the at least one reference image. The one or more measurements of the semiconductor structures in the inspection volume can be obtained using the deviation of the positions of the cross-section features from the corresponding (assigned) reference positions. In this way, the one or more measurements can be obtained with increased accuracy.

In an embodiment, the cross-section features are clustered according to their depth in the inspection volume. Cross-section features of the same or a similar depth in the inspection volume approximately lie on a line orthogonal to the FIB direction. Thus, the cross-section features can also be clustered according to their coordinate along the FIB direction. For each cluster, a cluster-specific lateral displacement can be obtained from the lateral displacements of the cross-section features in the cluster. The cluster-specific lateral displacement can be an average lateral displacement of the cross-section features in the cluster. Thus, for each cluster (with respect to depth or coordinate along the FIB direction) an average lateral displacement within the wedge cut can be determined. Alternatively, a median lateral displacement, or some lateral displacement obtained from the distribution of the lateral displacements within each cluster can be used, e.g., the average lateral displacement after removing outliers, etc. The cluster-specific lateral displacements can then be used instead of the lateral displacements to obtain the one or more measurements of the semiconductor structures in the inspection volume. In this way, more accurate and robust measurements can be obtained.

In an embodiment, the method further comprises generating a 3D representative semiconductor structure by adding lateral displacements between one or more positions of cross-section features and their reference positions to the positions of a reference semiconductor structure at the corresponding depths. Measurements can be taken of the 3D semiconductor structure by analyzing the deviations of the one or more positions of the cross-section features and their reference positions. Using the 3D representative semiconductor structure, further measurements can be obtained from the semiconductor structures in the inspection volume, e.g., concerning the shape or course or cross-sections of the 3D representative semiconductor structure. As distortions and further imaging effects contained in the wedge cut are also contained in the at least one reference image, the 3D representative semiconductor structure can be determined with increased accuracy from the single wedge cut due to the reduced distortions and further imaging effects. The 3D representative semiconductor structure can be used to obtain further measurements of the semiconductor structures in the inspection volume.

A 3D representative semiconductor structure refers to a virtual semiconductor structure that represents the semiconductor structures in the inspection volume, e.g., an average semiconductor structure within the inspection volume. It can, for example, be constructed from cross-section features of different semiconductor structures at different depths in the inspection volume. The representative semiconductor structure is generated using a reference semiconductor structure and the lateral displacements between the positions of cross-section features in the wedge cut and the reference positions of the cross-section features in at least one reference image. Instead of generating a 3D reconstruction of each semiconductor structure in the inspection volume, which is time-consuming, only a 3D representative semiconductor structure is reconstructed from a single wedge cut. Thus, computation time and desired memory properties are reduced and throughput is increased.

According to an aspect of the disclosure, the reference semiconductor structure is obtained from a reference volume of the same design as the inspection volume. The reference semiconductor structure can, for example, be obtained by selecting one of the semiconductor structures in the reference volume, or by averaging two or more semiconductor structures in the reference volume. The averaged semiconductor structures can have the same design.

According to an aspect of the disclosure, the reference semiconductor structure is generated from prior knowledge of the semiconductor structures in the inspection volume. In case prior knowledge on the semiconductor structures in the inspection volume is available, the reference semiconductor structure can be simulated. For example, the reference semiconductor structure can be simulated as a channel running perpendicular to the surface of the wafer with a specific shape or diameter. Alternatively, cross-sections of specific shapes or diameters, etc., of the reference semiconductor structure can be simulated at different depths and interpolated, etc.

In an example, the lateral displacements between the positions of the cross-section features in the wedge cut and the reference positions are clustered yielding cluster-specific lateral displacements as described above. The 3D representative semiconductor structure can then be generated by modifying, for each cluster, the position of the reference semiconductor structure at the corresponding cluster depth using the cluster-specific lateral displacement. For example, the 3D representative semiconductor structure can be generated by adding the cluster-specific lateral displacement for each cluster to the position of the reference semiconductor structure at the corresponding cluster depth. The centroid of the 3D representative semiconductor structure can, for example, be obtained by interpolating the modified positions of the reference semiconductor structure. The cross-section features can be mapped to the modified positions and interpolated to obtain a 3D reconstruction of the 3D representative semiconductor structure.

The reference image can be obtained from the inspection volume itself, for example from a cross-section image of the inspection volume parallel to the surface of the inspection volume or to the wafer support table at an arbitrary depth, e.g., an image of the surface of the inspection volume, e.g., a top view image or a bottom view image. The reference image does not contain another wedge cut of the inspection volume. By using the inspection volume itself to obtain the at least one reference image, no additional reference volume is used, thereby saving computation time, memory space and user effort. Furthermore, the distortions and further imaging effects in the at least one reference image are directly obtained from the inspection volume and, thus, similar to those in the wedge cut. However, defects or deviations from the norm can be contained in the inspection volume that will not be represented by the 3D representative semiconductor structure in the following.

In an embodiment of the disclosure, at least one reference image is obtained from a reference volume having at least substantially or predominantly the same design or having the same design as the inspection volume and being obtained under the same or similar manufacturing conditions as the inspection volume. The reference volume is different from the inspection volume. It can, for example, be acquired using different acquisition settings, a different machine, a different photolithography mask, a different point in time, etc. In an example, the at least one reference image comprises an image of a cross-section surface of the reference volume at an arbitrary angle and depth, e.g., a slice parallel to the surface of the reference volume or wafer support table, or a wedge cut of the reference volume, or an image of the surface of the reference volume, e.g., a top view image or a bottom view image. By deriving the reference positions of the cross-section features from the at least one reference image of the reference volume, the positions of the cross-section features in the wedge cut and the reference positions can be subject to the same distortions and further imaging effects as the inspection volume. The distortions are, thus, not contained in the lateral displacements between the positions of the cross-section features in the wedge cut and the corresponding reference positions. In this way, the accuracy of the one or more measurements and of the 3D representative semiconductor structure can be improved.

In an example, the reference volume comprises a different inspection volume, for example an inspection volume obtained using the same or a similar design file and the same or a similar manufacturing process as for obtaining the inspection volume. By using a different reference volume to obtain the at least one reference image, it can be made sure that the at least one reference image does not contain any defects or deviations from the norm. Thus, all defects or deviations from the norm can be preserved in the 3D representative semiconductor structure in the following. However, the distortions and further imaging effects are not necessarily identical to those in the inspection volume. In addition, the generation of the reference volume uses computation time, memory space and user effort.

In an example, the reference volume is simulated, e.g., using a design such as a CAD file or some other model of the semiconductor structures in the reference volume. In this way, the reference volume can be defect-free. It can be free of distortions and further imaging effects. Alternatively, distortions and further imaging effects can be simulated in the reference volume.

In an example, the at least one reference image comprises a cross-section image of the inspection volume parallel to the surface of the inspection volume and/or a top view image of a reference volume or a reference wedge cut of a reference volume, wherein the reference volume is of at least substantially the same design as the inspection volume.

In an example, the reference positions are obtained using prior knowledge concerning the semiconductor structures in the reference volume. For example, the prior knowledge can comprise location information, for example prior knowledge on the position, the orientation or the angle of the semiconductor structures in the reference volume, or relative location information, for example, prior knowledge on the distance, relative orientation, minimum distance or intersections of two or more semiconductor structures in the reference volume. The prior knowledge can be used in addition to the at least one reference image to determine the reference positions of the cross-section features. For example, the reference positions of the cross-section features in the at least one reference image can first be detected using image analysis. The detected reference positions can then be modified or optimized using the prior knowledge, e.g., by fitting a regular grid to the detected reference positions, or by using the regular grid as a soft constraint such that the reference positions lie close to the regular grid but do not have to lie on the regular grid. In this way, more accurate reference positions may be obtained.

In an embodiment, the at least one reference image comprises a top view image of the reference volume. A top view image refers to an image of the surface of the reference volume that is obtained using the cross particle beam imaging system oriented perpendicular to the surface of the wafer support table, i.e., at an angle GE=0°. The top view image can be obtained under the same conditions as the inspection volume and, thus, can contain the same lateral distortions. The reference positions of the cross-section features can then be determined from the lateral positions of the cross-section features in the top view image. By deriving the reference positions of the cross-section features from the top view image, the positions of the cross section features in the wedge cut and the reference positions can be subject to the same distortions and further imaging effects. Therefore, the distortions and further imaging effects can be reduced, and the accuracy of the one or more measurements and of the 3D representative semiconductor structure can be improved. For example, under the assumption that the reference positions of the cross section features are identical at each depth of the inspection volume, the position of the cross section features in the top view image can be used as reference positions at all depths. Alternatively, a grid can be fitted to the positions of the cross section features in the top view image, e.g., a regular hexagonal grid or a grid obtained from a design file. In this way, the grid parameters can be tuned to achieve a higher accuracy of the reference positions of the cross-section features. This in turn can lead to a higher accuracy of the measurements and the 3D representative semiconductor structure. Even if the assumption of identical reference positions at all depths does not hold, the deviation of the positions of the cross-section features in the top view image from the reference positions can provide information on lateral distortions, which can also be used for tuning the reference positions at other depths of the inspection volume.

According to an embodiment of the disclosure, the at least one reference image comprises a reference wedge cut of a reference volume. The reference volume can be generated from the same or a similar design under the same or similar manufacturing conditions as the inspection volume. The reference wedge cut can be generated using the same imaging process as for obtaining the wedge cut of the inspection volume for investigation. The reference wedge cut can be generated under the same or similar manufacturing conditions and, thus, comprises the same or similar lateral and depth-dependent distortions and further imaging effects. The reference positions of the cross-section features can then be determined in the reference wedge cut. By using the reference wedge cut for determining the reference positions, the reference positions are affected by the same lateral and depth-dependent distortions and further imaging effects as the positions of the cross-section features. Thus, the distortions and further imaging effects can be reduced, and the accuracy of the one or more measurements and the 3D representative semiconductor structure can be improved.

In an example, the depth range of the wedge cut is identical to the depth range of one or more of the at least one reference images. When refocusing at the same depth range, the distortions are more similar than in case different depth ranges are used. In this way, the accuracy of the measurements and of the 3D representative semiconductor structure can be improved.

In an example, the at least one reference image comprises two or more reference images, e.g., a top view image of the reference volume and a reference wedge cut of the reference volume, etc. For example, grid parameters can then be adapted to fit reference positions of cross-section features obtained from all of the two or more reference images. In another example, reference positions obtained from two or more reference images can be averaged. In this way, the accuracy of the measurements and of the 3D representative semiconductor structure can be further improved.

In an example, the reference positions of the cross-section features are determined by solving an optimization problem. The optimization problem can, for example, comprise a system of equations or a regression problem. The optimization problem can, for example, fit a grid to a set of reference positions obtained from the at least one reference image. By solving an optimization problem, the accuracy of the measurements and of the 3D representative semiconductor structure can be improved.

According to an embodiment of the disclosure, the method for obtaining a 3D representative semiconductor structure from a single wedge cut further comprises obtaining one or more measurements from the 3D representative semiconductor structure. The measurements can, for example, comprise a tilt or wiggling of the representative semiconductor structure, a diameter variation measuring the thickness of the representative semiconductor structure, variations of further parameters of the representative semiconductor structure, defects, etc. Depending on the measurement, a 3D reconstruction of the 3D representative semiconductor structure can be used, or specific properties of the 3D representative semiconductor structure, e.g., the centroid line, can be sufficient to obtain measurements of the 3D representative semiconductor structure. The measurements can, for example, be obtained using predefined measurement specifications, e.g., indicating thresholds for specific parameters such as a maximum or minimum diameter, or by applying machine learning. A machine learning model can, for example, be trained to use a representation of the 3D representative semiconductor structure as input and a measurement as output, for example, a diameter, a defect type, a defect segmentation or a defect detection as output.

In an example, the method further comprises detecting defects from the one or more measurements of the 3D representative semiconductor structure. Defects can, for example, be detected by comparing the obtained measurements with norm measurements, e.g., predefined measurements, target measurements, probability distributions of measurements or intervals indicating acceptable values, minimum values or maximum values. Alternatively, a machine learning model can be trained to detect defects from measurements. The norm measurements can be obtained from sample data that is predominantly defect-free.

A computer program according to an embodiment of the disclosure comprises instructions which, when the program is executed by a computer, cause the computer to carry out a method according to any of the embodiments or examples described herein.

A computer-readable medium according to an embodiment of the disclosure, has a computer program executable by a computing device stored thereon, the computer program comprising code for executing a method according to any of the embodiments or examples described herein.

A dual beam device according to an embodiment of the disclosure is configured to perform any of the methods according to any of the embodiments or examples described herein.

The disclosure described by examples and embodiments is not limited to the embodiments and examples but can be implemented by those skilled in the art by various combinations or modifications thereof.

### BRIEF DESCRIPTION OF THE DRAWINGS

FIG. 1A illustrates a schematic diagram of a 3D memory structure;

FIG. 1B illustrates desired measurements of HAR structures in metrology applications;

FIG. 2A illustrates an imaging setup for imaging cross-sections parallel to the surface of the wafer;

FIG. 2B illustrates a sparse imaging setup for imaging a wedge cut of a 3D memory structure;

FIG. 3 illustrates a dual beam device for obtaining wedge cuts of wafers;

FIG. 4 illustrates a flow chart of a method for obtaining measurements of semiconductor structures in an inspection volume from a wedge cut;

FIG. 5 illustrates the generation of a 3D representative semiconductor structure from cross-section features of a single wedge cut;

FIGS. 6A-6E illustrate the generation of a 3D representative semiconductor structure from a reference semiconductor structure and lateral displacements between positions of cross-section features and reference positions;

FIG. 7 shows a top view image of an inspection volume;

FIG. 8 shows a reference volume and a reference wedge cut; and

FIG. 9 schematically illustrates a dual beam device according to an embodiment of the disclosure, which can be used for obtaining measurements of semiconductor structures in an inspection volume.

### DETAILED DESCRIPTION

In the following, various exemplary embodiments of the disclosure are described and schematically shown in the figures. Throughout the figures and the description, same reference numbers are used to describe same features or components. Dashed lines indicate optional features.

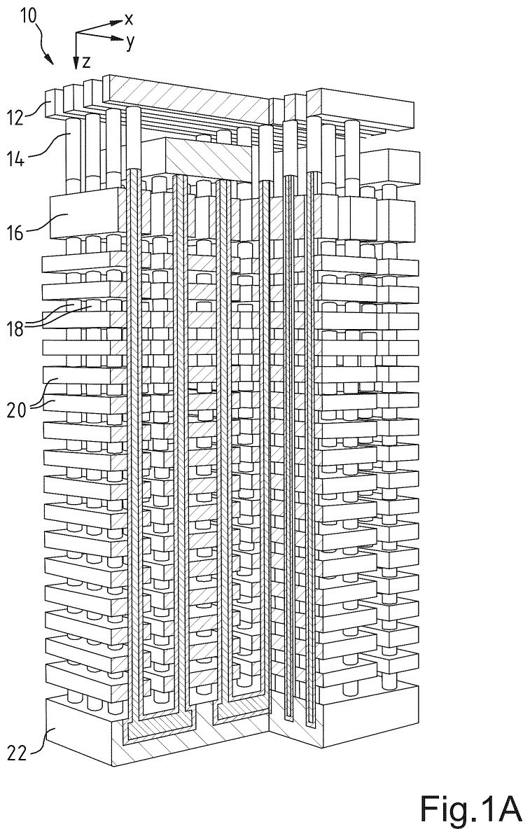

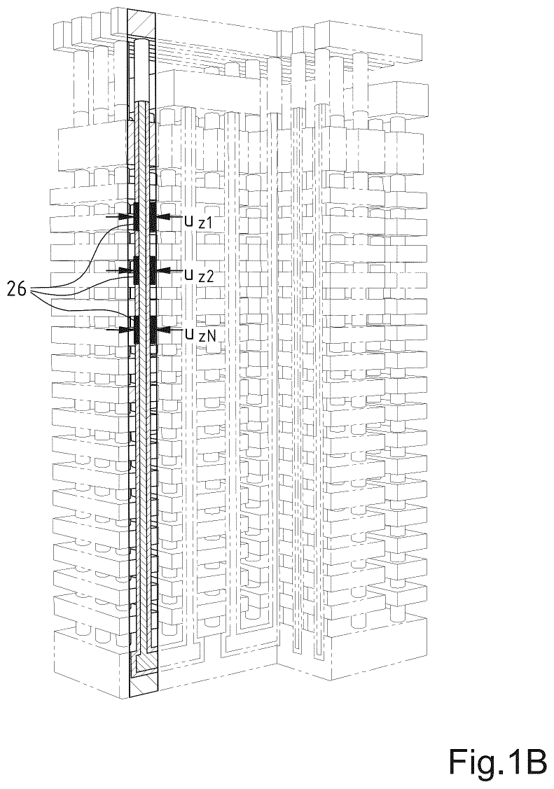

FIG. 1A illustrates a schematic diagram of an inspection volume 10 in the form of a 3D memory structure (a NAND-structure) of a wafer. The top and bottom portions of the structure pertain to gate logic and comprise bit lines 12, source lines 14, select gates 16, and back gates 22. Throughout the memory structure 10, semiconductor structures 18 in the form of densely arranged HAR structures (channels) run perpendicular to the surface of the wafer. Word-lines 20 run parallel to the surface of the wafer (in x-y-direction) at specific depths. FIG. 1B illustrates desired measurements 26 of semiconductor structures 18 for metrology applications, e.g., channel positions or channel diameters at various depths or channel tilts, channel orientations or wiggling (deviation of the semiconductor structure from its target position).

To take measurements of 3D semiconductor structures, cross-section images can be used. These cross-section images can be generated using a dual beam device comprising at least a FIB column and a charged particle beam imaging system, e.g., a scanning electron microscope (SEM).

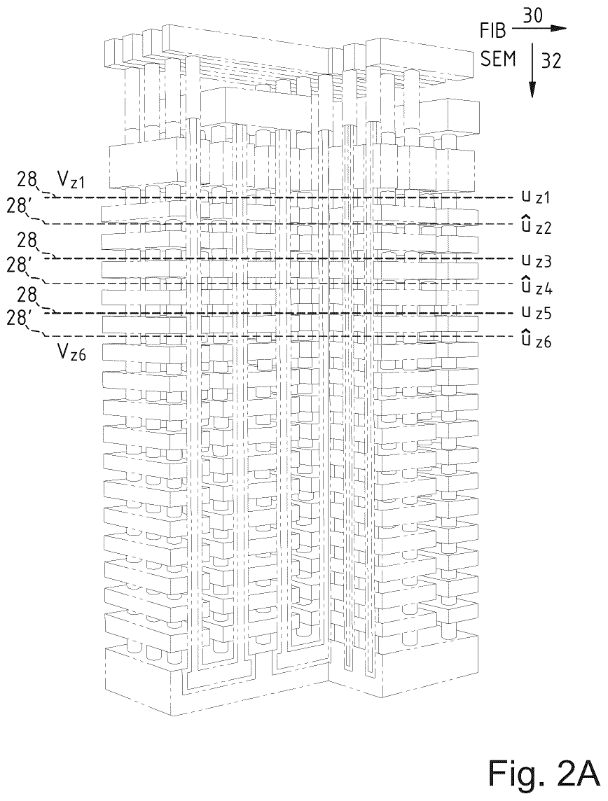

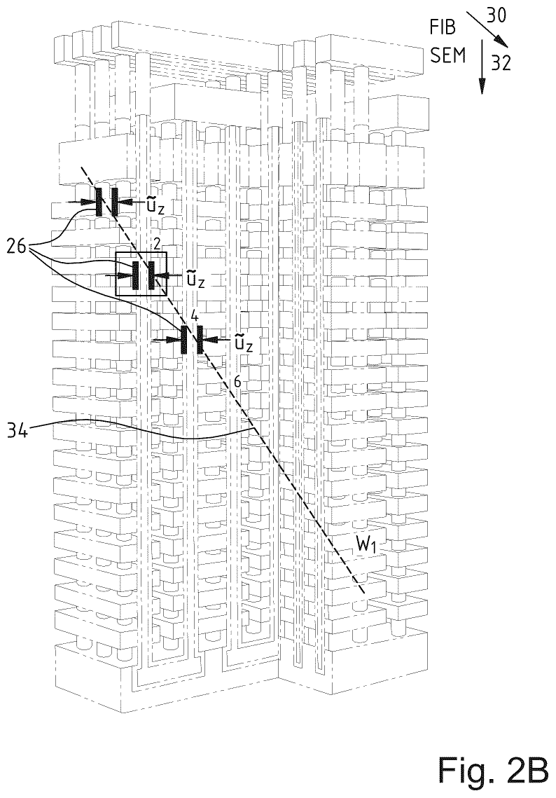

FIG. 2A illustrates a common imaging setup for imaging cross-section surfaces 28 parallel to the surface of the wafer in a slice and imaging technique. The FIB column mills the surface of the wafer in the FIB direction 30 parallel to the surface of the wafer, i.e., along slice planes, thereby forming cross-section surfaces 28 of the wafer. The charged particle beam imaging system, e.g., in form of a SEM, images the cross-section surfaces 28 in the SEM direction 32 orthogonal to the surface of the wafer, thereby forming cross-section images. A cross-section image can be parallel to the surface of the wafer, or it can be oriented at any other angle with respect to the wafer surface.

FIG. 2B illustrates a sparse imaging setup for imaging a wedge cut. The FIB column mills the surface of the wafer in the FIB direction 30, which forms an angle of about 45° with respect to the wafer surface. The SEM is oriented perpendicular to the wafer surface. The desired measurements 26 of the semiconductor structures 18 at different depths in the wafer can all be derived from different lateral positions of the semiconductor structures 18 in a single wedge cut 34. However, due to distortions in the wedge cut, the measurements 26 can only be obtained with limited accuracy.

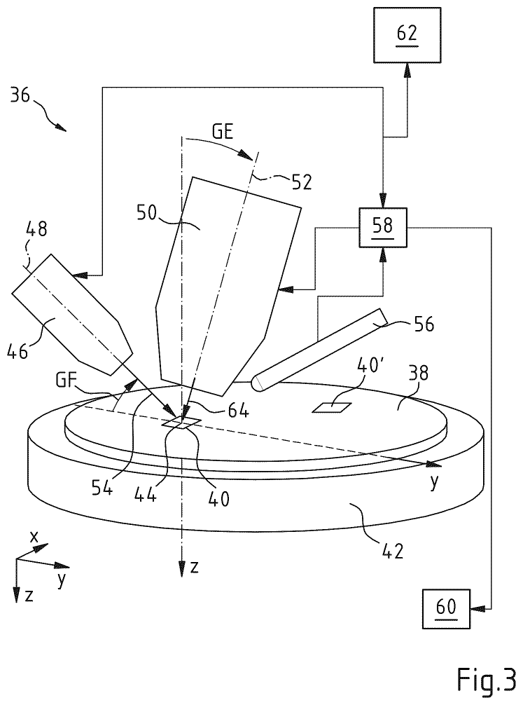

FIG. 3 illustrates a dual beam device 36 for obtaining wedge cuts of wafers 38. A wafer 38 is provided with several measurement sites 40 and 40′, the measurement sites being for example defined in a location map generated from an inspection tool or from design information. The wafer 38 is placed on a wafer support table 42. A measurement site 40 of the wafer 38 is aligned with a five-axis wafer stage (not shown) at the intersection point 44 of the dual-beam device 36, comprising a FIB column 46 with a FIB optical axis 48 and a charged particle beam (CPB) imaging system 50 with a CPB optical axis 52. At the intersection point 44 of both optical axes of FIB and CPB imaging system, the wafer surface is arranged at slant angle GF to the FIB optical axis 48. The CPB optical axis 52 forms a slant angle GE with the z-axis, which is perpendicular to the wafer plane. The FIB optical axis 48 and the CPB optical axis 52 can lie in a plane that is orthogonal to the surface of the wafer support table 42. With a FIB 54 impinging under a slant angle GF on the surface of the wafer 38, slanted cross-section surfaces are milled into the wafer 38 by ion beam milling at the inspection site 40 under approximately the slant angle GF between 20° and 60°. In the example of FIG. 3, the slant angle GF is approximately 30°. The actual slant angle can deviate from the slant angle GF by up to 1° to 4° due to the beam divergency of the focused ion beam, for example a Gallium-Ion beam. With the charged particle beam imaging system 50 inclined under angle GE to the wafer normal, images of the milled surfaces are acquired. In the example of FIG. 3, the angle GE is below 15°. During imaging, a beam of charged particles is scanned by a scanning unit of the CPB imaging system 50 along a scan path over a cross-section surface of the wafer 38 at measurement site 40, and secondary particles as well as scattered particles are generated. A particle detector 56 collects at least some of the secondary particles and scattered particles and communicates the particle count to a control unit 58. Control unit 58 is in control of the charged particle beam imaging system 50, of the FIB column 46 and the FIB 54, and is connected to a control unit 60 to control the position of the wafer 38 mounted on the wafer support table 42 via the wafer stage (not shown). Control unit 58 communicates with operation unit 62, which triggers placement and alignment, for example, of measurement site 40 of the wafer 38 at the intersection point 44 via wafer stage movement and triggers repeatedly operations of FIB milling, image acquisition and stage movements. Each intersection surface is imaged using a substantially vertical charged particle imaging beam 64, generated by, for example, a scanning electron microscope or any other charged particle beam microscope such as a Helium-Ion microscope (HIM). The process is further described in WO 2021/180600 A1, which is incorporated by reference herein.

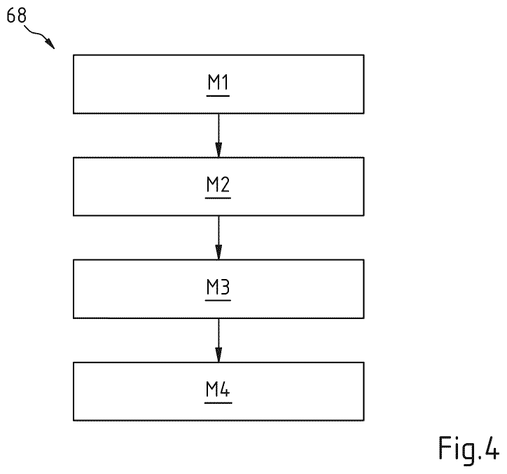

FIG. 4 illustrates a flow chart of a method 68 for obtaining one or more measurements of semiconductor structure from a single wedge cut of an inspection volume according to an embodiment of the disclosure. The method comprises: obtaining the wedge cut of the inspection volume by exposing a cross-section surface in the inspection volume by milling into the inspection volume with a FIB column arranged under a slant angle GF, and imaging the cross-section surface with a charged particle beam imaging system to obtain the wedge cut in a step M1; determining positions of cross-section features of semiconductor structures in the wedge cut in a step M2; determining reference positions of cross-section features from at least one reference image of the semiconductor structures in a step M3; obtaining the one or more measurements of the semiconductor structures in the inspection volume using lateral displacements between the positions of the cross-section features and the reference positions in a step M4.

The positions of the cross-section features of the semiconductor structures in the wedge cut 34 as well as the reference positions in the at least one reference image are lateral positions. The positions can be obtained relative to some coordinate system. The cross-section features can be detected in the wedge cut 34 and in the at least one reference image using image analysis methods, e.g., edge detection, contour extraction such as Active Contours, centroid computation, geometric shape fitting, Hough transforms, pattern matching, energy optimization methods such as variational methods or graph cuts, machine learning methods such as object detection, recognition or segmentation methods, etc.

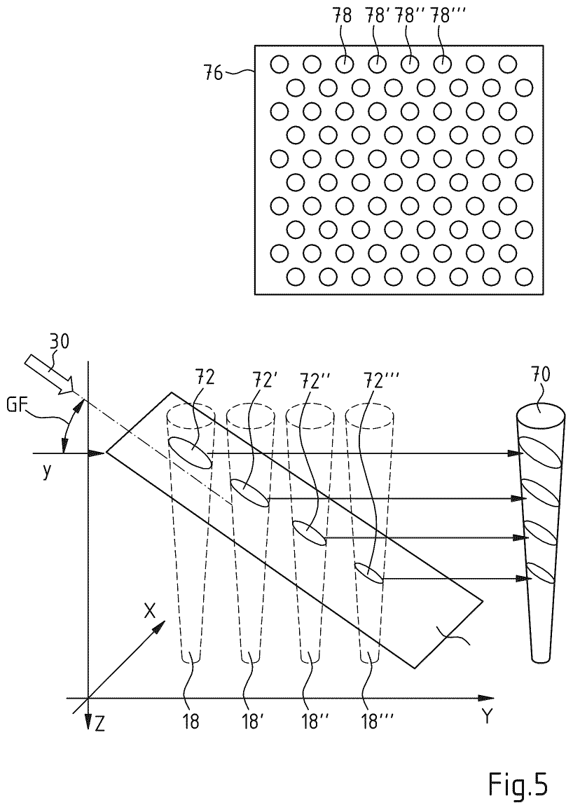

FIG. 5 illustrates the generation of one or more measurements of semiconductor structures 18, 18′, 18″, 18′″ in an inspection volume 10 from a single wedge cut 34. The wedge cut 34 is obtained using a FIB column at a slant angle GF for milling in a FIB direction 30. Positions 73 of the cross section features 72, 72′, 72″, 72′″ can be obtained using image analysis. Furthermore, reference positions 78, 78′, 78″, 78′″ of the cross-section features can be obtained using at least one reference image 76. Using the deviations of the positions of the cross-section features 72, 72′, 72″, 72′″ in the wedge cut 34 from the reference positions 78, 78′, 78″, 78′″ of the cross-section features in the at least one reference image 76, lateral displacements in the x-y plane can be obtained. From the lateral displacements measurements of the semiconductor structures can be obtained—for example, in case the semiconductor structures 18, 18′, 18″, 18′″ in the inspection volume 10 have an identical vertical profile or a predefined variation of a vertical profile. In case the at least one reference image 76 is obtained using the same or a similar design and the same or similar manufacturing conditions as for the inspection volume, distortions and further imaging effects are reduced by using the at least one reference image 76 to obtain the reference positions 78, 78′, 78″, 78′″ instead of using, for example, a predefined regular hexagonal grid.

Using the positions of the cross-section features 72, 72′, 72″, 72′″ in the wedge cut 34, a 3D representative semiconductor structure 70 can be reconstructed by stacking the cross-section features 72, 72′, 72″, 72″″ of different semiconductor structures 18, 18′, 18″, 18′″ to form a single representative semiconductor structure 70. This involves the assumption that all semiconductor structures 18, 18′, 18″, 18′″ within the inspection volume 10 have an identical vertical profile or a predefined variation of a vertical profile. The lateral displacements can be used to modify a reference semiconductor structure 69 to obtain a 3D representative semiconductor structure 70. Using the 3D representative semiconductor structure further measurements, e.g., of the shape or cross-sections, of the 3D representative semiconductor structure can be obtained.

More specifically, for each of the cross-section features 72, 72′, 72″, 72′″ in the form of a channel cross-section in the wedge cut 34, the position in form of the centroid (xᵢ, yᵢ) in the wedge cut 34 can be measured (for i=1 . . . . N cross-section features of HAR channels). As described above, the depth of a cross-section centroid (xᵢ, yᵢ) can be determined using the further semiconductor structures, e.g., the word-lines, or trigonometric functions and the angles GE and GF and the location of the inspection volume. Under the assumption that all semiconductor structures 18, 18′, 18″, 18′″, e.g., channels, in the field of view have the same shape and orientation, a 3D representative semiconductor structure 70 can be obtained.

Let

$${x}_{i}^{ref} and {y}_{i}^{ref}$$

indicate the reference position of the centroid of the i-th semiconductor structure. Then the 3D representative semiconductor structure can be obtained using the deviations or lateral displacements

$$( {x}_{i} - {x}_{i}^{r e f} , {y}_{i} - {y}_{i}^{ref} , z ( {x}_{i} , {y}_{i} ) ) .$$

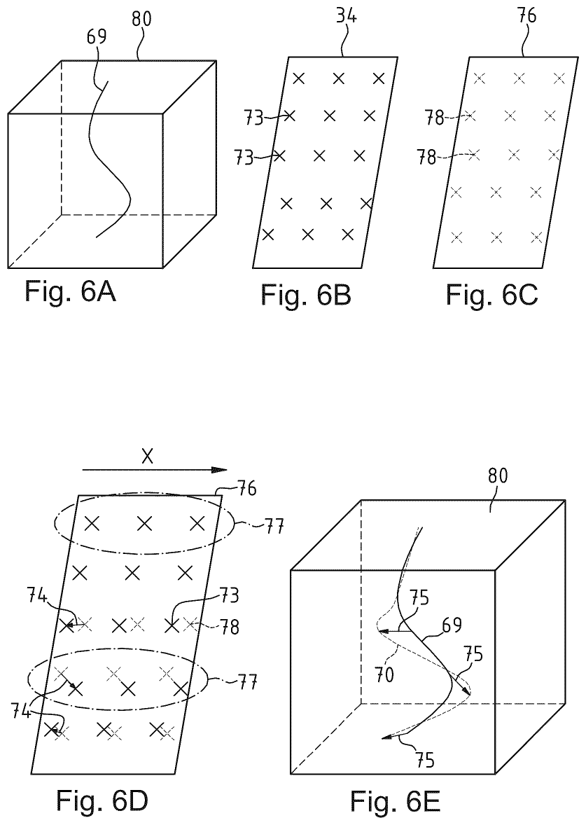

In an example, these lateral displacements can be clustered with respect to their depth in the inspection volume. For each cluster a cluster-specific lateral displacement can then be obtained as described further below with respect to FIGS. 6A-6E.

To obtain measurements of the semiconductor structures 70, functions \hat{x}(z) and ŷ(z) can, for example, be defined to describe the lateral displacement 74 of the representative semiconductor structure 70 over depth z. The lateral position of a channel cross-section centroid (xᵢ, yᵢ) at a given depth z can be defined as

$${x}_{i} = {x}_{i}^{ref} + \hat{x} ( z )$$

$${y}_{i} = {y}_{i}^{ref} + \hat{y} ( z ) .$$

From the functions \hat{x}(z) and ŷ(z) the tilt and wiggling of a representative semiconductor structure 70, for example of a representative channel, in the field of view can be determined. The functions \hat{x}(z) and ŷ(z) can be obtained by solving an optimization problem, for example a regression problem, to fit functions î(z) and ŷ(z) to the deviations

$$\hat{x} ( {z}_{i} ) = {x}_{i} - {x}_{i}^{ref}$$

$$\hat{y} ( {z}_{i} ) = {y}_{i} - {y}_{i}^{ref} .$$

The regression problem assumes parametric functions for \hat{x}(z) and ŷ(z), e.g., polynomials of a specific degree, e.g., second degree, Splines or any other parametric functions, and these parametric functions are fitted to the lateral displacements between the cross-section feature positions and the reference positions

$$( {x}_{i} - {x}_{i}^{ref} , {y}_{i} - {y}_{i}^{r e f} , z ( {x}_{i} , {y}_{i} ) ) .$$

Prior knowledge on the functions \hat{x}(z) and ŷ(z), e.g., a maximum value, a start or end value, etc. can be added by applying constraints or using Lagrange multipliers. Thus, for a sufficient number of measured positions of cross-section features 72, 72′, 72″, 72′″, i.e., channel centroids, and corresponding reference positions 78, 78′, 78″, 78′″ the functions \hat{x}(z) and ŷ(z) can be estimated. To obtain a 3D representative semiconductor structure, the functions \hat{x}(z) and ŷ(z) can be used to modify a reference semiconductor structure 69, for example by modifying the centroids of the reference semiconductor structure 69.

The single wedge cut 34 can, therefore, be used to obtain measurements of the semiconductor structures in the inspection volume. It can also be used to generate a 3D reconstruction of a representative semiconductor structure 70, e.g., to reconstruct the 3D-geometry of a representative channel of the 3D memory stack. From the 3D representative semiconductor structure 70, for example, further measurements can be obtained, e.g., a defect type or a defect signature can be identified, e.g., using defect specifications or machine learning. A machine learning model could, for example, be trained to detect or classify a defect using the functions \hat{x}(z) and ŷ(z) or a 3D representative semiconductor structure as input data and a defect detection, segmentation or classification as output.

The reference positions

$$( {x}_{i}^{r e f} , {y}_{i}^{r e f} )$$

can be obtained in various ways. One way is to use prior knowledge, for example to assume a predefined grid, e.g., a regular hexagonal grid or some irregular grid, on which the reference positions lie. The grid can, for example, be defined by a single point, an orientation and a distance between the semiconductor structures 18, 18′, 18″, 18′″. These parameters could be optimized together with the functions \hat{x}(z) and ŷ(z). However, due to distortions and further imaging effects in the wedge cut 34, the measurements and the 3D representative semiconductor structure 70 lack accuracy.

Alternatively, the reference positions 78, 78′, 78″, 78′″ can be obtained from at least one reference image 76 of the semiconductor structures 18, 18′, 18″, 18′″ as illustrated in FIG. 5. A reference image 76 refers to an acquired or simulated image. The at least one reference image 76 can be acquired using the same imaging system as used for acquiring the inspection volume 10, or a different imaging system. The at least one reference image 76 can be simulated, e.g., using a design file of the wafer. The appearance of a simulated reference image 76 can be adapted to the appearance of acquired images, e.g., by using machine learning techniques such as a generative adversarial models. The at least one reference image 76 can be obtained from a reference volume 80 of the same or at least substantially the same or a similar design and using the same or similar manufacturing process as for the inspection volume 10. Alternatively, the reference volume 80 can comprise an artificial volume, e.g. simulated semiconductor structures such as polygons obtained from a design file.

The reference positions 78, 78′, 78″, 78′″ in the at least one reference image 76 can be optimized by solving an optimization problem, e.g., an overdetermined system of equations. For example, a grid can be fitted to the at least one reference image, e.g., by adapting the pitch (distance between reference positions), the scale and/or the offset of the grid. By using at least one reference image 76, the imaging conditions, the layout of the semiconductor structures and depth-dependent effects within the inspection volume can be represented by the at least one reference image 76. Thus, the effect of lateral or depth-dependent distortions or further imaging effects is reduced in the measurements and in the 3D representative semiconductor structure. In this way, the determination of the reference positions 78, 78′, 78″, 78′″ of the cross-section features 72, 72′, 72″, 72′″ and, thus, the accuracy of the measurements and of the 3D representative semiconductor structure 70 can be improved.

Cross-section features 72, 72′, 72″, 72′″ in the wedge cut 34 can then be assigned to cross-section features 72, 72′, 72″, 72′″ in the at least one reference image 76, e.g., by comparing the positions of the cross-section features 72, 72′, 72″, 72′″ in the wedge cut 34 to the reference positions 78, 78′, 78″, 78′″ in the at least one reference image 76. For example, a cross-section feature 72, 72′, 72″, 72′″ in the wedge cut 34 can be assigned to the closest cross-section feature 72, 72′, 72″, 72′″ in the at least one reference image 76. Alternatively or additionally, image analysis methods can be applied to find corresponding cross-section features 72, 72′, 72″, 72′″ in the wedge cut 34 and the reference image 76.

FIGS. 6A-6E illustrates the generation of a 3D representative semiconductor structure 70 from a reference semiconductor structure 69 and lateral displacements between positions 73 of cross-section features 72 and reference positions of the cross-section features 78.

FIG. 6A shows a reference volume 80 containing a reference semiconductor structure 69. The reference volume can be a different inspection volume comprising semiconductor structures of the same or at least substantially the same or a similar design obtained under the same or similar manufacturing conditions. Alternatively, the reference volume 80 can be simulated or obtained from a design, for example from the design of the inspection volume 10.

FIG. 6B shows a wedge cut 34 of an inspection volume 10. The wedge cut 34 comprises cross-section features 72. The positions 73 of the cross-section features 72 are indicated by crosses. The cross-section features 72 are from the group comprising points, lines, curves, edges, geometric shapes, for example centroids of cross-sections of HAR structures such as channels. The positions 73 of the cross-section features 72 can be obtained using image analysis techniques, for example pattern recognition methods, segmentation methods, or machine learning methods.

FIG. 6C shows a reference image 76 comprising reference positions 78 corresponding to the positions 73 of the cross-section features 72 in the wedge cut 34. The reference image 76 can be obtained from a reference volume 80 as described with respect to FIG. 6A. The reference image 76 can, for example, comprise a top view image of the reference volume 80 or a reference wedge cut of the reference volume 80. The depth range of the wedge cut 34 is identical to the depth range of the at least one reference image.

The reference positions of the cross-section features 72 could be determined with increased accuracy by solving an optimization problem. For example, prior knowledge can be used concerning the reference positions 78 of the cross-section features 72 in the at least one reference image 76. Such prior knowledge can, for example, be obtained by assuming the semiconductor structures 18 to be arranged on a grid. For example, they can be arranged on a regular hexagonal grid in the x-y plane of the inspection volume 10 and/or run vertically with respect to the wafer surface (in z-direction). The optimization problem can, for example, minimize the deviation of the positions of the cross-section features 72 in the at least one reference image 76 from the grid by optimizing the parameters of the grid, e.g., the scaling, the offset and the pitch (distance) between the grid points. The grid can also be used as a soft constraint in the optimization problem that encourages the reference positions to lie on a grid but does not require them to do so.

FIG. 6D illustrates an assignment of each cross-section feature 72 in the wedge cut 34 to a cross-section feature in the reference image 76. However, sometimes semiconductor structures are missing in the wedge cut 34 or in the reference image 76. In this case, almost all cross-section features 72 in the wedge cut 34 are assigned to cross-section features in the reference image 76. The lateral displacements 74 of the positions 73 of the cross-section features 72 from the reference positions 78 are computed. The cross-section features are roughly arranged on a line in x-direction. Positions with the same x-coordinate in the wedge cut 34 have the same depth in the inspection volume 10. To increase the robustness of the method, the lateral displacements 74 are clustered with respect to the depth of the cross-section features 72 in the inspection volume 10. In this case, the clustering can be accomplished with respect to the x-coordinates of the positions 73 of the cross-section features 72. The clusters 77, thus, contain cross-section features 72 arranged roughly at the same depth in the inspection volume 10. For each cluster 77, a cluster-specific lateral displacement 75 is obtained from the lateral displacements 74 of the cross-section features 72 in the cluster 77. The cluster-specific lateral displacement 75 can comprise a mean lateral displacement, a median lateral displacement, a lateral displacement obtained from the distribution of the lateral displacements within the cluster 77, e.g., the mean lateral displacement after removal of outliers, etc.

FIG. 6E illustrates the generation of the 3D representative semiconductor structure 70 by modifying, for each cluster 77, the position of the reference semiconductor structure 69 at the corresponding cluster depth using the cluster-specific lateral displacement 75. The 3D representative semiconductor structure 70 can, for example, be obtained by interpolating the modified positions of the reference semiconductor structure 69. The cross-section features 72 can be mapped to the modified positions of the reference semiconductor structure 69. A parametric 3D surface or parametric functions can be fitted to the stacked cross-section features 72 to obtain a 3D reconstruction of the 3D representative semiconductor structure 70. To obtain measurements, for example, the center line of the 3D representative semiconductor structure 70 as a function of depth Z can be computed. This function indicates, for example, a tilt or wiggling of the representative semiconductor structure 70 in z-direction.

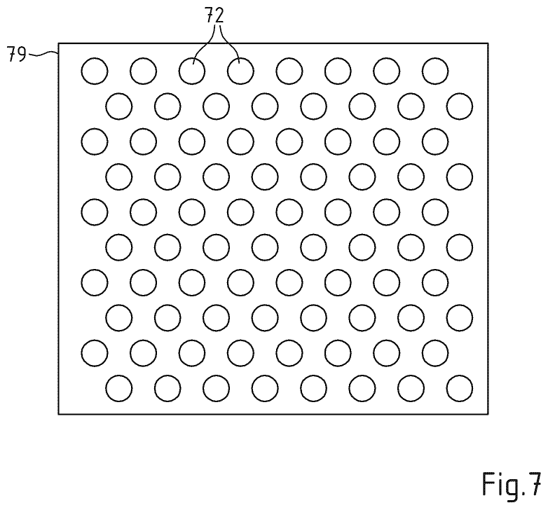

According to an embodiment of the disclosure illustrated in FIG. 7, the at least one reference image 76 comprises a top view image 79 of a reference volume 80, e.g., of the inspection volume 10. The top view image 79 is obtained using the charged particle beam imaging system at an angle GE=0° with respect to the surface of the wafer support table. From the top view image 79 of the reference volume 80, e.g., of the inspection volume 10, the layout of the cross-section features 72 on the wafer surface can be derived under the same imaging conditions as the inspection volume, thus including the same lateral distortions. The positions of the cross-section features 72 in the top view image 79 can, for example, be obtained using image analysis, e.g., using edge detection, centroid detection, contour detection, geometric shape detection methods such as active contours, Hough transforms or machine learning methods for object detection, recognition or segmentation. From the detected cross-section features 72 in the top view image 79 the reference positions 78 of the cross-section features 72 can, thus, be obtained with higher accuracy due to the (partial) compensation of lateral distortions.

In an example, a grid, for example a regular hexagonal grid, can be fitted to the detected positions of the cross-section features 72 in the top view image 79 of the reference volume 80 to obtain the reference positions 78 of the cross-section features 72. This can be accomplished by solving a system of equations, e.g., using a least squares method. In case, prior knowledge on the semiconductor structures 18 in the inspection volume is available, e.g., that all semiconductor structures 18 are oriented perpendicular to the wafer surface, the reference positions 78 obtained from the top view image 79 can be directly used as reference positions 78 throughout all depths of the inspection volume and, thus, compensate for lateral distortions and further imaging effects. Otherwise, information on lateral distortions can be derived from the deviations of the detected cross-section features 72 in the top view image 79 and the fitted regular grid. This information can be used to adapt reference positions 78 at larger depths in the inspection volume 10, which can, for example, be obtained from a design file.

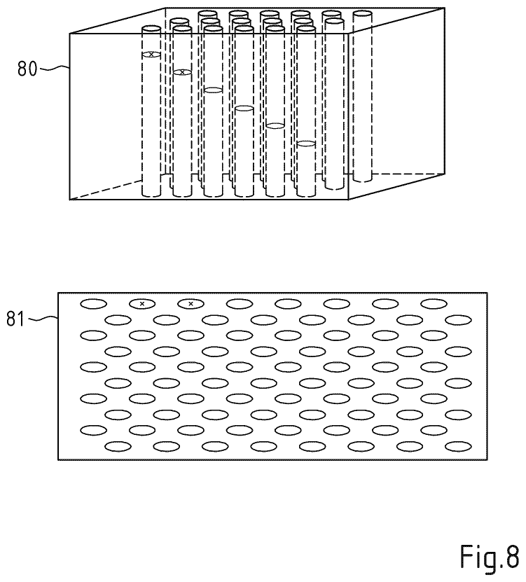

According to an embodiment of the disclosure illustrated in FIG. 8, the at least one reference image 76 comprises a reference wedge cut 81 of a reference volume 80, the reference volume 80 being generated from the same design and using the same or a similar manufacturing process as the inspection volume, and the reference wedge cut 81 being generated using the same imaging process as for the wedge cut 34. Since the reference volume 80 and the reference wedge cut 81 are obtained using the same imaging process, the same lateral and depth dependent distortions and further imaging effects affect the reference volume 80 and the reference wedge cut 81. The reference wedge cut 81 can, therefore, be used to improve the accuracy of the measurements and of the 3D representative semiconductor structure 70.

By using at least one reference image 76 that includes distortions and further imaging effects, the accuracy of the measurements and of the 3D representative semiconductor structure 70 can be improved.

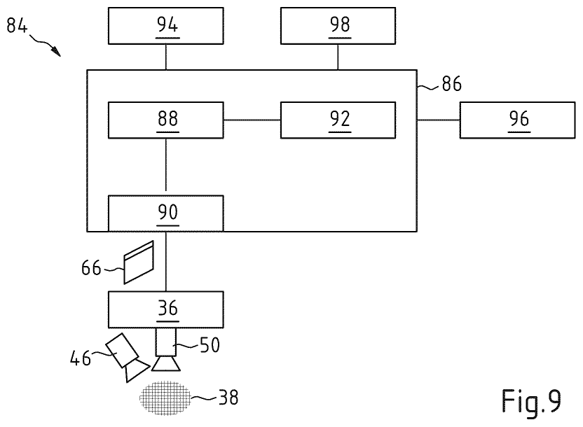

FIG. 9 schematically illustrates a system 84 according to an embodiment of the disclosure, which can be used for obtaining one or more measurements of semiconductor structures in an inspection volume from a single wedge cut 34 or for generating a 3D representative semiconductor structure from a single wedge cut 34 of an inspection volume. The system 84 includes a dual beam device 36 and a processing device 86. The dual beam device 36 is coupled to the processing device 86, e.g., via cable or wireless. The dual beam device 36 comprises a FIB column 46 and a charged particle beam imaging system 50 and is configured to acquire wedge cuts 34 of the wafer 38.

The dual beam device 36 can provide a wedge cut 34 to the processing device 86. The processing device 86 includes one or more processors 88, e.g., implemented as a CPU or GPU. The one or more processors 88 can receive the wedge cut 34 via an interface 90. The one or more processors 88 can load program code from one or more machine-readable hardware storage devices 92. The one or more processors 88 can execute the program code. Upon executing the program code, the one or more processors 88 perform techniques such as described herein, e.g., obtaining measurements from semiconductor structures in an inspection volume, generating a 3D representative semiconductor structure, detecting cross-section features in wedge cuts, top view images or inspection volumes, computing measurements from 3D representative semiconductor structures, detecting defects, etc. For example, the one or more processors 88 can perform the method shown in FIG. 4 upon loading program code from the one or more machine-readable hardware storage devices 92. The system 84 can optionally contain a user interface 94, e.g., for setting parameters, for indicating measurement specifications, for natural language processing, for reviewing cross-section features, etc. The system 84 can optionally contain a database 96. The database 96 can, for example, be used to load sets of measurement specifications. The system 84 can optionally contain a visualization device 98 for visualizing 3D representative semiconductor structures, cross-section features, measurements, measurement specifications, etc., to the user.

The methods disclosed herein can, for example, be used during research and development of wafers or during high volume manufacturing of wafers, or for process window qualification or enhancement. In addition, the methods disclosed herein can also be used for defect detection of X-ray imaging datasets of wafers, e.g., after packaging the semiconductor device for delivery.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment”, “according to an example” or “according to an aspect” in various places throughout this specification are not necessarily all referring to the same embodiment, example or aspect, but may. Furthermore, various features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

In some embodiments, the disclosure can be described by the following clauses:
1. A method 68 for obtaining one or more measurements of semiconductor structures 18 from a single wedge cut 34 of an inspection volume 10, the method 68 comprising:
   obtaining the wedge cut 34 of the inspection volume 10 by exposing a cross-section surface in the inspection volume 10 by milling into the inspection volume 10 with a FIB column 46 arranged under a slant angle GF, and imaging the cross-section surface with a charged particle beam imaging system 50 to obtain the wedge cut 34;
   determining positions of cross-section features 72 of semiconductor structures 18 in the wedge cut 34;
   determining reference positions of the cross-section features 72 from at least one reference image 76 of the semiconductor structures 18;
   obtaining the one or more measurements of the semiconductor structures 18 in the inspection volume 10 using lateral displacements 74 between the positions of the cross-section features 72 and the reference positions 78.
2. The method of clause 1, further comprising determining the depths of the cross-section features 72 in the inspection volume 10.
3. The method of any one of the preceding clauses, wherein cross-section features 72 in the wedge cut 34 are assigned to cross-section features 72 in the at least one reference image 76.
4. The method of any one of the preceding clauses, wherein the cross-section features 72 are clustered according to their depth in the inspection volume 10, wherein, for each cluster 77, a cluster-specific lateral displacement 75 is obtained from the lateral displacements 74 of the cross-section features 72 in the cluster 77, and wherein the cluster-specific lateral displacements 75 are used instead of the lateral displacements 74.
5. The method of clause 4, wherein the cluster-specific lateral displacement 75 is an average lateral displacement of the cross-section features 72 in the cluster 77.
6. The method of any one of the preceding clauses, further comprising generating a 3D representative semiconductor structure 70 by adding lateral displacements between one or more positions of cross-section features 72 and their reference positions to the positions of a reference semiconductor structure at the corresponding depths.
7. The method of clause 6, wherein the reference semiconductor structure is obtained from a reference volume 80 of the same design as the inspection volume 10.
8. The method of clause 6 or 7, wherein the reference semiconductor structure is generated from prior knowledge of the semiconductor structures in the inspection volume 10.
9. The method of any one of clauses 6 to 8, wherein the one or more measurements are obtained using the 3D representative semiconductor structure 70.
10. The method of any one of the preceding clauses, wherein the at least one reference image 76 is obtained from a reference volume 80 of the same design as the inspection volume 10.
11. The method of clause 10, wherein the reference volume 80 comprises the inspection volume 10 or one or more portions thereof.
12. The method of clause 10 or 11, wherein the at least one reference image comprises a top view image 79 of the reference volume 80.
13. The method of any one of clauses 10 to 12, wherein the at least one reference image comprises a reference wedge cut 81 of the reference volume 80.
14. The method of any one of the preceding clauses, wherein the depth range of the wedge cut 34 is identical to the depth range of the at least one reference image.
15. The method of any one of the preceding clauses, wherein the reference positions of the cross-section features 72 are determined by solving an optimization problem.
16. The method of any one of the preceding clauses, wherein the reference positions of the cross-section features 72 are determined using prior knowledge concerning the semiconductor structures 18 in the reference volume 80.
17. The method of any one of the preceding clauses, semiconductor structures 18 are high aspect ratio structures.
18. The method of any one of the preceding clauses, wherein the cross-section features 72 are from the group comprising points, lines, curves, edges, geometric shapes.
19. The method of any one of the preceding clauses, further comprising detecting defects from the one or more measurements of the semiconductor structures 18.
20. The method of any one of the preceding clauses, wherein the slant angle GF is measured with respect to the surface of a wafer support table 42 and lies between 20° and 80°, preferably between 25° and 45°, most preferably between 30° and 36°.
21. A computer program comprising instructions which, when the program is executed by a computer, cause the computer to carry out a method of any one of clauses 1 to 20.
22. A computer-readable medium, on which a computer program executable by a computing device is stored, the computer program comprising code for executing a method of any one of clauses 1 to 20.
23. A dual beam device configured to perform any of the methods according to any one of clauses 1 to 20.

In summary, the disclosure relates to a method 68 for obtaining one or more measurements of semiconductor structures from a single wedge cut 34 of an inspection volume 10, the method 68 comprising: obtaining the wedge cut 34 of the inspection volume 10 by exposing a cross-section surface in the inspection volume 10 by milling into the inspection volume 10 with a FIB column 46 arranged under a slant angle GF, and imaging the cross-section surface with a charged particle beam imaging system 50; determining positions of cross-section features 72 of semiconductor structures 18 in the wedge cut 34; determining reference positions of the cross-section features 72 from at least one reference image 76 of the semiconductor structures 18; obtaining the one or more measurements of the semiconductor structures 18 in the inspection volume 10 using lateral displacements 74 between the positions of the cross-section features 72 and the reference positions 78.

### REFERENCE NUMBER LIST

Inspection volume
12 Bit line
14 Source line
16 Select gate
18, 18′, 18″, 18′″ Semiconductor structure
Interfering structure
22 Back gate
26 Measurement
28 Interference-free cross section
FIB direction
32 SEM direction
34 Wedge cut
36 Dual beam device
38 Wafer
Measurement site
42 Wafer support table
44 Intersection point
46 FIB column
48 Optical axis
50 Charged particle beam imaging system
52 Optical axis
54 FIB
56 Particle detector
58 Control unit
60 Control unit
62 Operation unit
64 Charged particle imaging beam
68 Method
69 Reference semiconductor structure
70 3D representative semiconductor structure
72, 72′, 72″, 72′″ Cross-section feature
73 Position
74 Lateral displacement
75 Cluster-specific lateral displacement
76 Reference image
77 Cluster
78, 78′, 78″, 78′″ Reference position
79 Top view image
80 Reference volume
81 Reference wedge cut
84 System
86 Processing device
88 Processor
90 Interface
92 Hardware storage device
94 User interface
96 Database

What is claimed is:

1. A method of obtaining one or more measurements of semiconductor structures in an inspection volume of a sample, the method comprising:
using a FIB column to mill into an inspection volume to expose a cross-section surface in the inspection volume, the FIB column being arranged at a slant angle relative to a surface of a table supporting the sample;
imaging the cross-section surface with a charged particle beam imaging system to obtain an image of the cross-section surface;
determining positions of cross-section features of the semiconductor structures in the image of the cross-section surface;
determining reference positions of the cross-section features from at least one reference image of the semiconductor structures; and
obtaining the one or more measurements of the semiconductor structures in the inspection volume using lateral displacements between the positions of the cross-section features in the reference positions and the image of the cross-section surface.

2. The method of claim 1, further comprising determining depths of the cross-section features in the inspection volume.

3. The method of claim 1, comprising assigning cross-section features in the image of the cross-section surface to cross-section features in the at least one reference image of the semiconductor structures.

4. The method of claim 1, further comprising:
clustering the cross-section features according to their depth in the inspection volume to provide a plurality of clusters;
for each cluster, obtaining a cluster-specific lateral displacement from the lateral displacements of the cross-section features in the cluster; and
using the cluster-specific lateral displacements as the lateral displacements.

5. The method of claim 4, wherein each cluster-specific lateral displacement is an average lateral displacement of the cross-section features in the cluster.

6. The method of claim 1, further comprising generating a 3D representative semiconductor structure by adding lateral displacements between one or more positions of cross-section features and their reference positions to the positions of a reference semiconductor structure at the corresponding depths.

7. The method of claim 6, wherein at least one of the following holds:
the method further comprises obtaining the reference semiconductor structure from a reference volume of the same design as the inspection volume;
the method further comprises generating the reference semiconductor structure from prior knowledge of the semiconductor structures in the inspection volume; and
the one or more measurements are obtained using the 3D representative semiconductor structure.

8. The method of claim 1, wherein the at least one reference image comprises a cross-section image of the inspection volume parallel to a surface of the inspection volume, or the at least one reference image comprises a top view image of the inspection volume.

9. The method of claim 1, further comprising obtaining the at least one reference image from a reference volume of at least substantially the same design as the inspection volume.

10. The method of claim 9, wherein the at least one reference image comprises a top view image of the reference volume, or the at least one reference image comprises a reference cross-section surface of the reference volume.

11. The method of claim 1, wherein a depth range of the cross-section surface in the inspection volume is identical to a depth range of the at least one reference image.

12. The method of claim 1, wherein the reference positions of the cross-section features are determined by solving an optimization problem.

13. The method of claim 1, further comprising determining the reference positions of the cross-section features using prior knowledge concerning the semiconductor structures in the reference volume.

14. The method of claim 1, wherein the semiconductor structures are high aspect ratio structures.

15. The method of claim 1, wherein the cross-section features comprise features selected from the group consisting of points, lines, curves, edges, and geometric shapes.

16. The method of claim 1, further comprising detecting defects from the one or more measurements of the semiconductor structures.

17. The method of claim 1, wherein the slant angle is from 20° to 80°.

18. One or more machine-readable hardware storage devices comprising instructions that are executable by one or more processing devices to perform operations comprising the method of claim 1.

19. A system, comprising:
one or more processing devices; and
one or more machine-readable hardware storage devices comprising instructions that are executable by one or more processing devices to perform operations comprising the method of claim 1.

20. The system of claim 19, further comprising a dual beam device, wherein the dual beam device comprises:
the FIB column; and
the charged particle beam imaging system.
